(19) United States
(12) Patent Application Publication
(10) Pub. No.: US 2026/0203207 A1
(43) Pub. Date: Jul. 16, 2026

(54) LLR Generation with Gaussian Modeling and Machine Learning

(71) Applicant: SK hynix Inc., Gyeonggi-do (KR)

(72) Inventors: Pengfei HUANG, San Jose, CA (US); Fan ZHANG, San Jose, CA (US); Haobo WANG, San Jose, CA (US)

(21) Appl. No.: 19/015,640

(22) Filed: Jan. 10, 2025

(51) Int. Cl. G06F 12/02

(52) U.S. Cl. CPC G06F 12/0246

(57) ABSTRACT

A method and memory system for estimating parameters for reading data from a memory. The method determines respective counts of memory cell read patterns obtained by reading pages of the data from the memory with corresponding pre-determined read thresholds, wherein for a NAND PV state, two thresholds (RT1 and RT2) are obtained according to used page read thresholds; determines corresponding survival function values (SF1 and SF2); uses the two read thresholds (RT1 and RT2) and the corresponding survival function values (SF1 and SF2) to determine a mean μ and a standard deviation σ of a NAND PV state; and infers a soft read interval Δ and LLR values through a deep neural network (DNN) that takes, as an input, parameters (μ₁, σ₁) and (μ₂, σ₂) corresponding to respective means and standard deviations of two adjacent PV states having a read valley in between.

### BACKGROUND

### 1. Field

The present invention relates to reading data from solid state drives.

### 2. Description of the Related Art

The computer environment paradigm has shifted to ubiquitous computing systems that can be used anytime and anywhere. As a result, the use of portable electronic devices such as mobile phones, digital cameras, and notebook computers has rapidly increased. These portable electronic devices generally use a memory system having memory device(s), that is, data storage device(s). The data storage device is used as a main memory device or an auxiliary memory device of the portable electronic devices. Data storage devices using memory devices provide excellent stability, durability, high information access speed, and low power consumption, since they have no moving parts. Examples of data storage devices having such advantages include universal serial bus (USB) memory devices, memory cards having various interfaces, and solid state drives (SSD).

The SSD may include flash memory components and a controller, which includes the electronics that bridge the flash memory components to the SSD input/output (I/O) interfaces. The SSD controller can include an embedded processor that can execute functional components such as firmware. The SSD functional components are device specific, and in most cases, can be updated. One type of flash memory components is named NAND after the NAND logic gates in this SSD. The NAND-type flash memory may be written and read in blocks (or pages) which are generally much smaller than the entire memory space. The NAND-type operates primarily in memory cards, USB flash drives, solid-state drives, and similar products, for general storage and transfer of data.

In this context, embodiments of the present invention for processing scrambled NAND data arise.

### SUMMARY

In accordance with one embodiment of the present invention, there is provided a method for estimating parameters for reading data from a memory having a plurality of NAND program-voltage (PV) states. The method determines respective counts of memory cell read patterns obtained by reading pages of the data from the memory with corresponding pre-determined read thresholds, wherein for a NAND PV state, two thresholds (RT1 and RT2) are obtained according to used page read thresholds; based on the respective counts of the memory cell read patterns, determines corresponding survival function values (SF1 and SF2); uses the two read thresholds (RT1 and RT2) and the corresponding survival function values (SF1 and SF2) to determine a mean μ and a standard deviation σ of a NAND PV state; and uses a deep neural network (DNN) to infer a soft read interval Δ and LLR values, wherein the DNN takes, as an input, parameters (μ₁, σ₁) and (μ₂, σ₂) corresponding to respective means and standard deviations of two adjacent PV states having a read valley in between

In accordance with another embodiment of the present invention, there is provided a memory system comprising a storage having a plurality of NAND program-voltage (PV) states therein; and a controller in communication with the storage. The controller is configured to: determine respective counts of memory cell read patterns obtained by reading pages of the data from the memory with corresponding pre-determined read thresholds, wherein for a NAND PV state, two thresholds (RT1 and RT2) are obtained according to used page read thresholds; based on the respective counts of the memory cell read patterns, determine corresponding survival function values (SF1 and SF2); use the two read thresholds (RT1 and RT2) and the corresponding survival function values (SF1 and SF2) to determine a mean μ and a standard deviation σ of a NAND PV state; and use a deep neural network (DNN) to infer a soft read interval Δ and LLR values, wherein the DNN takes, as an input, parameters (μ₁, σ₁) and (μ₂, σ₂) corresponding to respective means and standard deviations of two adjacent PV states having a read valley in between.

### BRIEF DESCRIPTION OF THE DRAWINGS

FIG. 1 is a high level block diagram illustrating an error correcting system in accordance with embodiments of the present invention.

FIG. 2 is a block diagram schematically illustrating a memory system in accordance with embodiments of the present invention.

FIG. 3 is a block diagram illustrating a memory system in accordance with embodiments of the present invention.

FIG. 4 is a circuit diagram illustrating a memory block of a memory device in accordance with embodiments of the present invention.

FIG. 5 is a diagram illustrating a storage system in accordance with embodiments of the present invention.

FIG. 6A is a diagram illustrating a format of a codeword to be stored in a storage system in accordance with embodiments of the present invention.

FIGS. 6B and 6C are diagrams of a low-density parity check decoder nodes and a LDPC matrix in accordance with embodiments of the present invention.

FIG. 7A is a diagram illustrating distributions of states for different types of cells of a memory device.

FIG. 7B is a diagram illustrating an example of Gray coding for a multi-level cell (MLC).

FIG. 7C is a diagram illustrating state distributions for pages of a multi-level cell (MLC).

FIG. 7D is a diagram illustrating an example of Gray coding for a triple-level cell (TLC).

FIG. 7E is a diagram illustrating state distributions for pages of a triple-level cell (TLC).

FIG. 8A is a diagram of a neural network in accordance with embodiments of the present invention.

FIG. 8B is a diagram of a trained neural network in accordance with embodiments of the present invention.

FIG. 9A is a diagram showing relationships between program voltage states and the read thresholds according to one embodiment of the present invention when different multi-level cells are read.

FIG. 9B is diagram depicting read thresholds and surviving functions in accordance with another embodiment of the present disclosure.

FIG. 10A is a diagram showing relationships between program voltage states and the read thresholds according to one embodiment of the present invention when a least significant bit page is read.

FIG. 10B is a diagram showing relationships between program voltage states and the read thresholds according to one embodiment of the present invention when a center significant bit page is read.

FIG. 10C is a diagram showing relationships between program voltage states and the read thresholds according to one embodiment of the present invention when a most significant bit page is read.

FIG. 11A is a diagram showing relationships between PV states and the read thresholds according to one embodiment of the present invention when a single level cell is read with a multi-level cell.

FIG. 11B is a diagram showing relationships between PV states and the read thresholds according to another embodiment of the present invention when a single level cell is read with a different multi-level cell.

FIG. 11C is a diagram showing relationships between PV states and the read thresholds according to another embodiment of the present invention when a single level cell is read with different multi-level cell.

FIG. 12 is a flow chart illustrating a method for estimating parameters for reading data from a memory having a plurality of NAND program-voltage (PV) states according to another embodiment of the present invention.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will convey the scope of the present invention to those skilled in the art. Throughout the disclosure, like reference numerals refer to like parts throughout the various figures and embodiments of the present invention.

The invention can be implemented in numerous ways, including as a process; an apparatus; a system; a composition of matter; a computer program product embodied on a computer readable storage medium; and/or a processor, such as a processor suitable for executing instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being suitable for performing a task may be implemented as a general component that is temporarily suitable for performing the task at a given time or a specific component that is manufactured to perform the task. As used herein, the term ‘processor’ refers to one or more devices, circuits, and/or processing cores suitable for processing data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention encompasses numerous alternatives, modifications and equivalents. Numerous specific details are set forth in the following description in order to provide a thorough understanding of the invention. These details are provided for the purpose of example, and the invention may be practiced according to the claims without some or all of these specific details. For the purpose of clarity, technical material that is known in the technical fields related to the invention has not been described in detail so that the invention is not unnecessarily obscured.

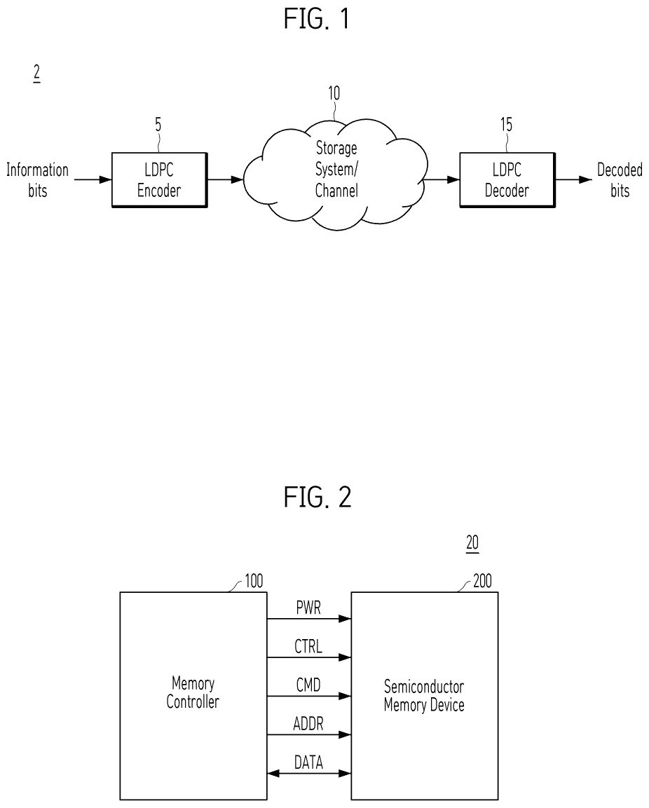

FIG. 1 is a high-level block diagram illustrating an error correcting system 2, in accordance with embodiments of the present invention. More specifically, the high-level block diagram in FIG. 1 shows error correcting system 2 including an encoder 5 and a decoder 15 using for example LDPC coding and decoding algorithms. That is, error correcting system 2 may include a LDPC encoder 5 and a LDPC decoder 15, although other coding and decoding algorithms can be used.

The LDPC encoder 5 may receive information bits including data which is desired to be stored in a storage system 10 (such as in memory system 20 of FIG. 2). The LDPC encoder 5 may encode the information bits to output LDPC encoded data. The LDPC encoded data from the LDPC encoder 5 may be written to a storage device or memory device of the storage system 10. In various embodiments, the storage device may include a variety of storage types or media. In some embodiments, during being written to or read from the storage device, data is transmitted and received over a wired and/or wireless channel. In this case, the errors in the received codeword may be introduced during transmission of the codeword.

When the stored data in the storage system 10 is requested or otherwise desired (e.g., by an application or user which stored the data), the LDPC decoder 15 may perform LDPC decoding data received from the storage system 10, which may include some noise or errors. In various embodiments, the LDPC decoder 15 may perform LDPC decoding using the decision and/or reliability information for the received data. The decoded bits generated by the LDPC decoder 15 are transmitted to the appropriate entity (e.g., the user or application which requested it). With proper encoding and decoding, the information bits match the decoded bits.

FIG. 2 is a block diagram schematically illustrating a memory system 20 in accordance with an embodiment of the present invention.

Referring FIG. 2, the memory system 20 may include a memory controller 100 and a semiconductor memory device 200.

The memory controller 100 may control overall operations of the semiconductor memory device 200.

The semiconductor memory device 200 may perform one or more erase, program, and read operations under the control of the memory controller 100. The semiconductor memory device 200 may receive a command CMD, an address ADDR and data DATA through input/output lines. The semiconductor memory device 200 may receive power PWR through a power line and a control signal CTRL through a control line. The control signal may include a command latch enable (CLE) signal, an address latch enable (ALE) signal, a chip enable (CE) signal, a write enable (WE) signal, a read enable (RE) signal, and so on.

The memory controller 100 and the semiconductor memory device 200 may be integrated in a single semiconductor device. For example, the memory controller 100 and the semiconductor memory device 200 may be integrated in a single semiconductor device such as a solid state drive (SSD). The solid state drive may include a storage device for storing data therein. When the semiconductor memory system 20 is used in an SSD, operation speed of a host (not shown) coupled to the memory system 20 may remarkably improve.

The memory controller 100 and the semiconductor memory device 200 may be integrated in a single semiconductor device such as a memory card. For example, the memory controller 100 and the semiconductor memory device 200 may be integrated in a single semiconductor device to configure a memory card such as a PC card of personal computer memory card international association (PCMCIA), a compact flash (CF) card, a smart media (SM) card, a memory stick, a multimedia card (MMC), a reduced-size multimedia card (RS-MMC), a micro-size version of MMC (MMCmicro), a secure digital (SD) card, a mini secure digital (miniSD) card, a micro secure digital (microSD) card, a secure digital high capacity (SDHC), and a universal flash storage (UFS).

For another example, the memory system 20 may be provided as one of various elements including an electronic device such as a computer, an ultra-mobile PC (UMPC), a workstation, a net-book computer, a personal digital assistant (PDA), a portable computer, a web tablet PC, a wireless phone, a mobile phone, a smart phone, an e-book reader, a portable multimedia player (PMP), a portable game device, a navigation device, a black box, a digital camera, a digital multimedia broadcasting (DMB) player, a 3-dimensional television, a smart television, a digital audio recorder, a digital audio player, a digital picture recorder, a digital picture player, a digital video recorder, a digital video player, a storage device of a data center, a device capable of receiving and transmitting information in a wireless environment, one of electronic devices of a home network, one of electronic devices of a computer network, one of electronic devices of a telematics network, a radio-frequency identification (RFID) device, or elements devices of a computing system.

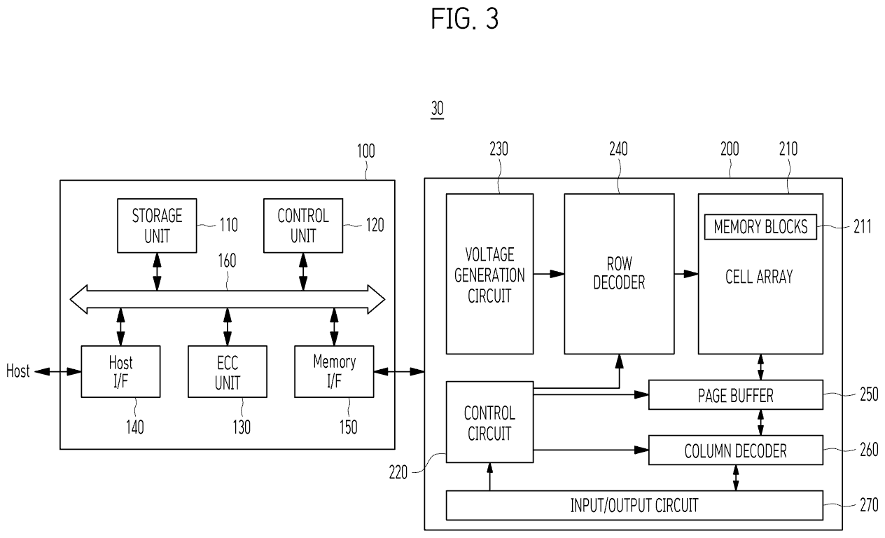

FIG. 3 is a detailed block diagram illustrating various embodiments of memory system 30 in accordance with one embodiment of the present invention. For example, memory system 30 of FIG. 3 may depict the storage system 10 shown in FIG. 1 or the memory system 20 shown in FIG. 2.

Referring to FIG. 3, the memory system 30 may include the memory controller 100 and the semiconductor memory device 200. The memory system 30 may operate in response to a request from a host device, and in particular, store data to be accessed by the host device.

The host device may be implemented with any one of various kinds of electronic devices. In some embodiments, the host device may include an electronic device such as a desktop computer, a workstation, a three-dimensional (3D) television, a smart television, a digital audio recorder, a digital audio player, a digital picture recorder, a digital picture player, a digital video recorder and a digital video player. In some embodiments, the host device may include a portable electronic device such as a mobile phone, a smart phone, an e-book, an MP3 player, a portable multimedia player (PMP), and a portable game player.

The memory device 200 may store data to be accessed by the host device.

The memory device 200 may be implemented with a volatile memory device such as a dynamic random access memory (DRAM) and a static random access memory (SRAM) or a non-volatile memory device such as a read only memory (ROM), a mask ROM (MROM), a programmable ROM (PROM), an erasable programmable ROM (EPROM), an electrically erasable programmable ROM (EEPROM), a ferroelectric random access memory (FRAM), a phase change RAM (PRAM), a magnetoresistive RAM (MRAM) and a resistive RAM (RRAM).

The controller 100 may control storage of data in the memory device 200. For example, the controller 100 may control the memory device 200 in response to a request from the host. The controller 100 may provide the data read from the memory device 200, to the host, and store the data provided from the host into the memory device 200.

The controller 100 may include a storage unit 110, a control unit 120, the error correction code (ECC) unit 130, a host interface 140 and a memory interface 150, which are coupled through a bus 160.

The storage unit 110 may serve as a working memory of the memory system 10 and the controller 100, and store data for driving the memory system 10 and the controller 100. When the controller 100 controls operations of the memory device 200, the storage unit 110 may store data used by the controller 100 and the memory device 200 for such operations as read, write, program and erase operations.

The storage unit 110 may be implemented with a volatile memory. The storage unit 110 may be implemented with a static random access memory (SRAM) or a dynamic random access memory (DRAM). As described above, the storage unit 110 may store data used by the host device in the memory device 200 for the read and write operations. To store the data, the storage unit 110 may include a program memory, a data memory, a write buffer, a read buffer, a map buffer, and so forth.

Referring to FIG. 3, the control unit 120 may control general operations of the memory system 30, and a write operation or a read operation for the memory device 200, in response to a write request or a read request from the host device. The control unit 120 may drive firmware, which is referred to as a flash translation layer (FTL), to control the general operations of the memory system 10. For example, the FTL may perform operations such as logical to physical (L2P) mapping, wear leveling, garbage collection, and bad block handling. The L2P mapping is known as logical block addressing (LBA).

The ECC unit 130 may detect and correct errors in the data read from the memory device 200 during the read operation. The ECC unit 130 may not correct error bits when the number of the error bits is greater than or equal to a threshold number of correctable error bits, and may output an error correction fail signal indicating failure in correcting the error bits.

In some embodiments, the ECC unit 130 may perform an error correction operation based on a coded modulation such as an LDPC code, a Bose-Chaudhuri-Hocquenghem (BCH) code, a turbo code, a turbo product code (TPC), a Reed-Solomon (RS) code, a convolution code, a recursive systematic code (RSC), a trellis-coded modulation (TCM), a Block coded modulation (BCM), and so on. The ECC unit 130 may include all circuits, systems or devices for the error correction operation.

As shown in FIG. 3, host interface 140 may communicate with the host device through one or more of various interface protocols such as a universal serial bus (USB), a multi-media card (MMC), a peripheral component interconnect express (PCI-e or PCIe), a small computer system interface (SCSI), a serial-attached SCSI (SAS), a serial advanced technology attachment (SATA), a parallel advanced technology attachment (PATA), an enhanced small disk interface (ESDI), and an integrated drive electronics (IDE).

The memory interface 150 may provide an interface between the controller 100 and the memory device 200 to allow the controller 100 to control the memory device 200 in response to a request from the host device. The memory interface 150 may generate control signals for the memory device 200 and process data under the control of the control unit (e.g., CPU) 120. When the memory device 200 is a flash memory such as a NAND flash memory, the memory interface 150 may generate control signals for the memory and process data under the control of the control unit 120.

The memory device 200 may include a memory cell array 210, a control circuit 220, a voltage generation circuit 230, a row decoder 240, a page buffer 250, a column decoder 260, and an input/output circuit 270. The memory cell array 210 may include a plurality of memory blocks 211 and may store data therein. The voltage generation circuit 230, the row decoder 240, the page buffer 250, the column decoder 260 and the input/output circuit 270 form a peripheral circuit for the memory cell array 210. The peripheral circuit may perform a program, read, or erase operation of the memory cell array 210. The control circuit 220 may control the peripheral circuit.

The voltage generation circuit 230 may generate operation voltages having various levels. For example, in an erase operation, the voltage generation circuit 230 may generate operation voltages having various levels such as an erase voltage and a pass voltage.

The row decoder 240 may be connected to the voltage generation circuit 230, and the plurality of memory blocks 211. The row decoder 240 may select at least one memory block among the plurality of memory blocks 211 in response to a row address RADD generated by the control circuit 220, and transmit operation voltages supplied from the voltage generation circuit 230 to the selected memory blocks among the plurality of memory blocks 211.

The page buffer 250 may be connected to the memory cell array 210 through bit lines BL (not shown). The page buffer 250 may precharge the bit lines BL with a positive voltage, transmit/receive data to/from a selected memory block in program and read operations, or temporarily store transmitted data, in response to a page buffer control signal generated by the control circuit 220.

The column decoder 260 may transmit/receive data to/from the page buffer 250 or transmit/receive data to/from the input/output circuit 270.

The input/output circuit 270 may transmit, to the control circuit 220, a command and an address, transmitted from an external device (e.g., the memory controller 100), transmit data from the external device to the column decoder 260, or output data from the column decoder 260 to the external device, through the input/output circuit 270.

The control circuit 220 may control the peripheral circuit in response to the command and the address.

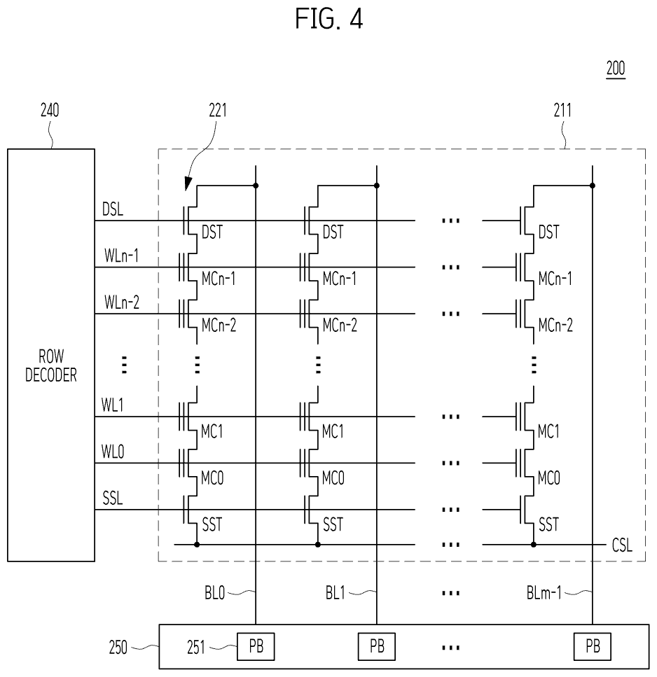

FIG. 4 is a circuit diagram illustrating a memory block of a semiconductor memory device in accordance with an embodiment of the present invention. For example, a memory block of FIG. 4 may be the memory blocks 211 of the memory cell array 210 shown in FIG. 3.

Referring to FIG. 4, the memory blocks 211 may include a plurality of cell strings 221 coupled to bit lines BL0 to BLm−1, respectively. The cell string of each column may include one or more drain selection transistors DST and one or more source selection transistors SST. A plurality of memory cells or memory cell transistors may be serially coupled between the selection transistors DST and SST.

Each of the memory cells MC0 to MCn−1 may be formed of a multi-level cell (MLC) storing data information of multiple bits in each cell. The cell strings 221 may be electrically coupled to the corresponding bit lines BL0 to BLm−1, respectively.

In some embodiments, the memory blocks 211 may include a NAND-type flash memory cell. However, the memory blocks 211 are not limited to the NAND flash memory, but may include NOR-type flash memory, hybrid flash memory in which two or more types of memory cells are combined, and one-NAND flash memory in which a controller is embedded inside a memory chip.

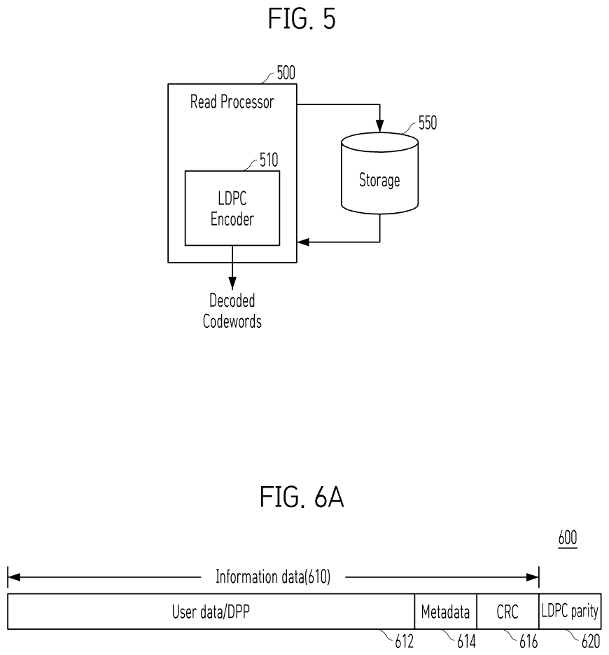

FIG. 5 is a diagram illustrating a storage system in accordance with embodiments of the present invention.

Referring to FIG. 5, the storage system may include a storage 550 and a memory controller such as a read processor 500. The read processor 500 may perform a read operation for data stored in the storage 550. During the read operation, the read processor 500 may read data from the storage 550, which may include some noise or errors, and perform error correction for the read data. In some embodiments, the read processor 500 may include a decoder, for example, the LDPC decoder 510 which may perform LDPC decoding. The read processor 500 may also perform BF decoding and MS decoding. The read processor 500 may include a receiver (not shown) for receiving data from the storage 550.

When the stored data in the storage 550 is requested or otherwise desired (e.g., by an application or user which stored the data), the LDPC decoder 510 may receive data from the storage 550. The received data may include some noise or errors. The LDPC decoder 510 may perform detection on the received data and output decision and/or reliability information. The LDPC decoder 510 may include one of a soft detector and a hard detector. Either the soft detector or the hard detector can provide channel information for decoders, such as the LDPC decoder. For example, the soft detector may output reliability information and a decision for each detected bit. On the other hand, the hard detector may output a hard decision on each bit without providing corresponding reliability information. As an example, the hard detector may output as the hard decision that a particular bit is a “1” or a “0” without indicating how certain or sure the detector is in that decision. In contrast, the soft detector may output a decision and reliability information associated with the decision. In general, reliability information indicates how certain the detector is in a given decision. In one example, a soft detector may output a log-likelihood ratio (LLR) where the sign indicates the decision (e.g., a positive value corresponds to a “1” decision and a negative value corresponds to a “0” decision) and the magnitude indicates how sure or certain the detector is in that decision (e.g., a large magnitude indicates a high reliability or certainty).

Also, LDPC decoder 510 may perform LDPC decoding using the decision and/or reliability information. LDPC decoder 510 may include one of a soft decoder and a hard decoder. The soft decoder utilizes both the decision and the reliability information to decode the codeword. The hard decoder utilizes only the decision values to decode the codeword. The decoded bits generated by the LDPC decoder 510 are transmitted to the appropriate entity (e.g., the user or application which requested it). With proper encoding and decoding, the information bits match the decoded bits.

In various embodiments, the system shown in FIG. 5 may be implemented using a variety of techniques including an application-specific integrated circuit (ASIC), a field-programmable gate array (FPGA), and/or a general purpose processor (e.g., an Advanced RISC Machine (ARM) core).

LDPC codes may be represented by bipartite graphs. One set of nodes (e.g., the variable or bit nodes) may correspond to elements of the codeword, and the other set of nodes (e.g., check nodes) may correspond to the set of parity check constraints satisfied by the code words.

### Existing Decoding Schemes

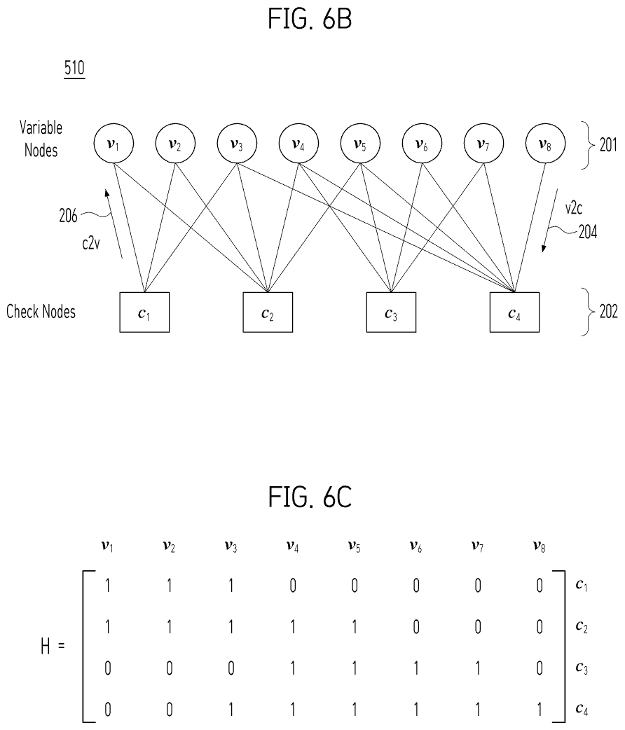

FIG. 6A is a diagram illustrating a format of a codeword 600 to be stored in a storage system. Referring to FIG. 6A, the codeword 600 may include information data 610 and parity data 620. In some embodiments, the codeword 600 may be generated by LDPC codes. In other words, the information data 610 may be protected by LDPC codes, and the parity data 620 may be LDPC parity. The information data 610 may include user data with data path protection (DPP) 612, meta-data 614 and cyclic redundancy check (CRC) parity bits 616. A CRC code which is an error-detecting code commonly used in digital networks and storage devices may detect accidental changes to raw data.

In a typical LDPC decoder, if the LDPC checksum is zero, the decoder may be terminated. The CRC parity bits 616 will be computed based on the decoded user data 612 and meta-data 614 after the LDPC decoding. If the computed CRC parity bits match the decoded CRC parity bits, decoding may be successful. Otherwise, a mis-correction may be declared.

In some embodiments of the present invention, it is supposed that x=[x₀, x₁, . . . , x_{N-1}] is a bit vector, and H=[h_{i,j}] is an M×N low-density parity-check matrix with a binary value h_{i,j} at the intersection of row i and column j. Then each row of H provides a parity check for x. If x is a codeword of H, it has xH^{T}=0.

FIG. 6B is a diagram of a bipartite graph showing aspects of node communications in LDPC decoder 510. The decoder 510 includes a number of variable nodes 201, which are part of a variable node unit (VNU). A total of eight variable nodes (VNs) 201 are shown in FIG. 6B, labeled as v1-v8. The VNs 201 communicate with a series of check nodes (CNs) 202 that are part of a check node unit (CNU) described in more detail below. A total of four check nodes are shown in FIG. 6B, labeled as c1-c4. Other respective numbers and arrangements of the respective nodes 201, 202 can be provided. The lines connecting the variable nodes 201 to the check nodes 202 represent two-way communications paths for transmitting messages therebetween. These messages may go from variable to check node as indicated by v2c direction 204 or from check to variable node, as indicated by c2v direction 206. In FIG. 6C, the number of “1s” in the corresponding rows and columns of the LDPC matrix H shown represents the interconnections between variable and check nodes in the graph of FIG. 6B.

In LDPC decoding, a syndrome update may check to see if all of the errors have been removed from the codeword. For example, if for parity check matrix H (e.g., matrix of FIG. 6C), the LDPC checksum ĉH=0, then the syndrome update can determine that decoding is successful and all errors have been removed from the codeword. If so, the LDPC decoding stops decoding and outputs ĉ=[ĉ1, ĉ2, . . . ĉN] as the decoded output.

If the LDPC checksum is not equal to zero, the decoded codeword (i.e., ĉ) is not output and another decoding iteration is performed until a maximum number of iterations, which may be predefined, is reached. In other words, the variable node update calculates new messages V2C messages and new LLR values, the check node update calculates new messages C2V messages, and the codeword update calculates a new codeword and checks if the product of the new codeword and the parity check matrix is 0, that is ĉH=0.

If a correct codeword is not found, the iterations continue with another update from the variable nodes using the messages that they received from the check nodes to decide if the bit at their position should be a zero or a one by a majority rule. The variable nodes then send this hard decision message to the check nodes that are connected to them. The iterations continue until a correct codeword is found.

With reference back to FIG. 6C, the term “weight” or “degree” as used herein refers to the number of entries in a row or a column of the H matrix that have the number “1” listed. As seen in FIG. 6C, the first row associated with c1 has a weight or degree of 3, while the second row associated with c2 has a weight or degree of 5. Viewed differently, the weight of a particular check node may also be defined as the degree of connectivity of the variable nodes to the check node, as shown in FIG. 6B, where the weight or degree of c1 would be 3 and the weight or degree of c2 would be 5.

In some embodiments, an LDPC decoding operation is performed according to bit flipping decoding. In bit-flipping decoders, the decoder may process a fixed number W of variable nodes (VN) in one clock-cycle. That is for each of the VNs to be processed in a cycle, the decoder counts the number of neighboring check nodes (CN) that are unsatisfied and compares this number with a threshold T. If the count is larger than the threshold T, the decoder flips the current bit-value of the VN. The variable nodes are each processed one-by-one from the first variable node to the last variable node.

For irregular codes, as noted above, the column weight, or column degree, or number of non-zero elements in a column, can vary across different columns. The irregularity of a parity check matrix of an irregular LDPC code can be described by the column weight distribution, which describes how many bits are with what column degree etc.

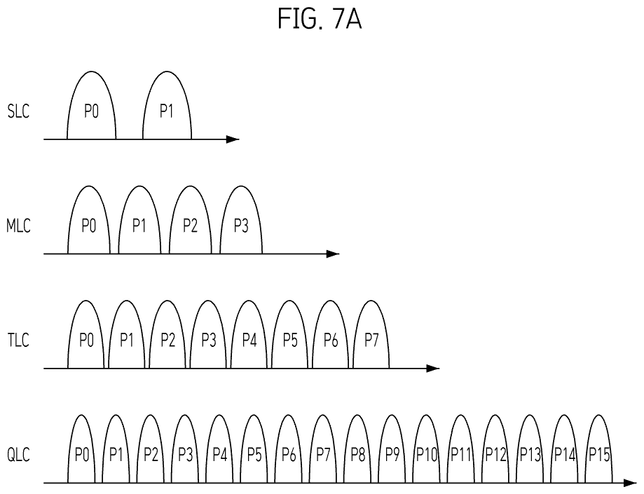

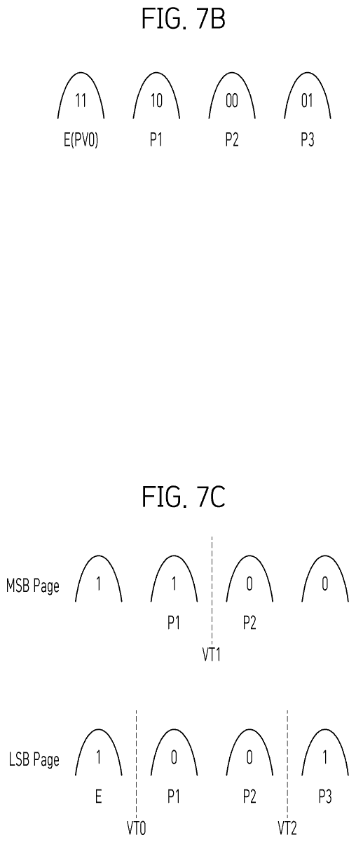

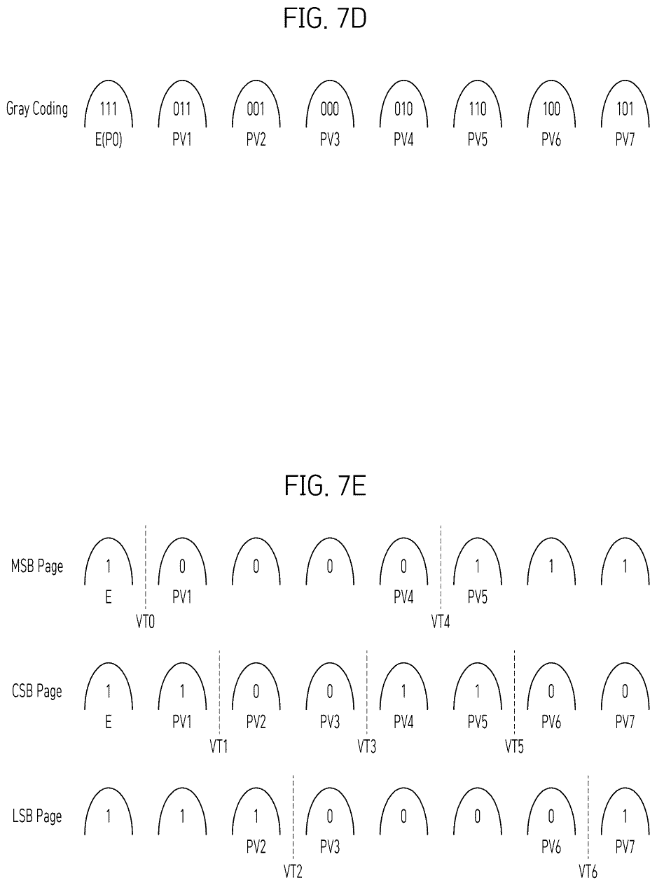

FIG. 7A is a diagram illustrating distributions of states or program voltage (PV) levels for different types of cells of a memory device.

Referring to FIG. 7A, each of memory cells may be implemented with a specific type of cell, for example, a single level cell (SLC) storing 1 bit of data, a multi-level cell (MLC) storing 2 bits of data, a triple-level cell (TLC) storing 3 bits of data, or a quadruple-level cell (QLC) storing 4 bits of data. Usually, all memory cells in a particular memory device are of the same type, but that is not a requirement.

An SLC may include two states P0 and P1. P0 may indicate an erase state, and P1 may indicate a program state. Since the SLC can be set in one of two different states, each SLC may program or store 1 bit according to a set coding method. An MLC may include four states P0, P1, P2 and P3. Among these states, P0 may indicate an erase state, and P1 to P3 may indicate program states. Since the MLC can be set in one of four different states, each MLC may program or store two bits according to a set coding method. A TLC may include eight states P0 to P7. Among these states, P0 may indicate an erase state, and P1 to P7 may indicate program states. Since the TLC can be set in one of eight different states, each TLC may program or store three bits according to a set coding method. A QLC may include 16 states P0 to P15. Among these states, P0 may indicate an erase state, and P1 to P15 may indicate program states. Since the QLC can be set in one of sixteen different states, each QLC may program or store four bits according to a set coding method.

Referring back to FIGS. 2 and 3, the memory device 200 may include a plurality of memory cells (e.g., NAND flash memory cells). The memory cells are arranged in an array of rows and columns as shown in FIG. 3. The cells in each row are connected to a word line (e.g., WL0), while the cells in each column are coupled to a bit line (e.g., BL0). These word and bit lines are used for read and write operations. During a write operation, the data to be written (‘1’ or ‘0’) is provided at the bit line while the word line is asserted. During a read operation, the word line is again asserted, and the threshold voltage of each cell can then be acquired from the bit line. Multiple pages may share the memory cells that belong to (i.e., are coupled to) the same word line. When the memory cells are implemented with MLCs, the multiple pages include a most significant bit (MSB) page and a least significant bit (LSB) page. When the memory cells are implemented with TLCs, the multiple pages include an MSB page, a center significant bit (CSB) page and an LSB page. When the memory cells are implemented with QLCs, the multiple pages include an MSB page, a center most significant bit (CMSB) page, a center least significant bit (CLSB) page and an LSB page. The memory cells may be programmed using a coding scheme (e.g., Gray coding) in order to increase the capacity of the memory system 10 such as SSD.

FIG. 7B is a diagram illustrating an example of coding for a multi-level cell (MLC).

Referring to FIG. 7B, an MLC may be programmed using a set coding. An MLC may have 4 program states, which include an erased state E (or PV0) and a first program state PV1 to a third program state PV3. The erased state E (or PV0) may correspond to “11.” The first program state P1 may correspond to “10.” The second program state P2 may correspond to “00.” The third program state P3 may correspond to “01.”

In the MLC, as shown in FIG. 7C, there are 2 types of pages including LSB and MSB pages. 1 or 2 thresholds may be applied in order to retrieve data from the MLC. For an MSB page, the single threshold value is VT1. VT1 distinguishes between the first program state P1 and the second program state P2. For an LSB page, 2 thresholds include a threshold value VT0 and a threshold value VT2. VT0 distinguishes between the erased state E and the first program state P1. VT2 distinguishes between the second program state P2 and the third program state P3.

FIG. 7D is a diagram illustrating an example of Gray coding for a triple-level cell (TLC).

Referring to FIG. 7D, a TLC may be programmed using Gray coding. A TLC may have 8 program states, which include an erased state E (or PV0) and a first program state PV1 to a seventh program state PV7. The erased state E (or PV0) may correspond to “110.” The first program state PV1 may correspond to “011.” The second program state PV2 may correspond to “001.” The third program state PV3 may correspond to “000.” The fourth program state PV4 may correspond to “010.” The fifth program state PV5 may correspond to “110.” The sixth program state PV6 may correspond to “100.” The seventh program state PV7 may correspond to “101.”

In the TLC, as shown in FIG. 7E, there are 3 types of pages including LSB, CSB and MSB pages. 2 or 3 thresholds may be applied in order to retrieve data from the TLC. For an MSB page, 2 thresholds include a threshold value VT0 that distinguishes between an erase state E and a first program state PV1 and a threshold value VT4 that distinguishes between a fourth program state PV4 and a fifth program state PV5. For a CSB page, 3 thresholds include VT1, VT3 and VT5. VT1 distinguishes between a first program state PV1 and a second program state PV2. VT3 distinguishes between a third program state PV3 and the fourth program state PV4. VT5 distinguishes between the fourth program state PV5 and the sixth program state PV6. For an LSB page, 2 thresholds include VT2 and VT6. VT2 distinguishes between the second program state PV2 and the third program state PV3. VT6 distinguishes between the sixth program state PV6 and a seventh program state PV7.

After a memory array including a plurality of memory cells is programmed as described above, when a read operation is performed on the memory array using a certain voltage reference value such as a read threshold (i.e., read voltage level), the electrical charge levels of the memory cells (e.g., threshold voltage levels of transistors of memory cells) are compared to one or more voltage reference values (also called “read voltage level” or “read threshold”) to determine the state of individual memory cells. When a certain read threshold is applied to the memory array, those memory cells that have threshold voltage levels higher than the certain voltage reference value are turned on and detected as “on” cell, whereas those memory cells that have threshold voltage levels lower than the certain voltage reference value are turned off and detected as “off” cell, for example. Therefore, each read threshold is arranged between neighboring threshold voltage distribution windows corresponding to different programmed states so that each read threshold can distinguish such programmed states by turning on or off the memory cell transistors.

However, NAND voltage distribution can vary with the lifetime of the SSD. In order to achieve high reliability, optimal hard read thresholds need to be obtained before ECC decoding so that the fail bit count (FBC) is minimized. In addition, in order to have the best LDPC soft correction power, optimal soft read thresholds and associated log-likelihood ratio (LLR) values should be estimated and used for LDPC soft decoding.

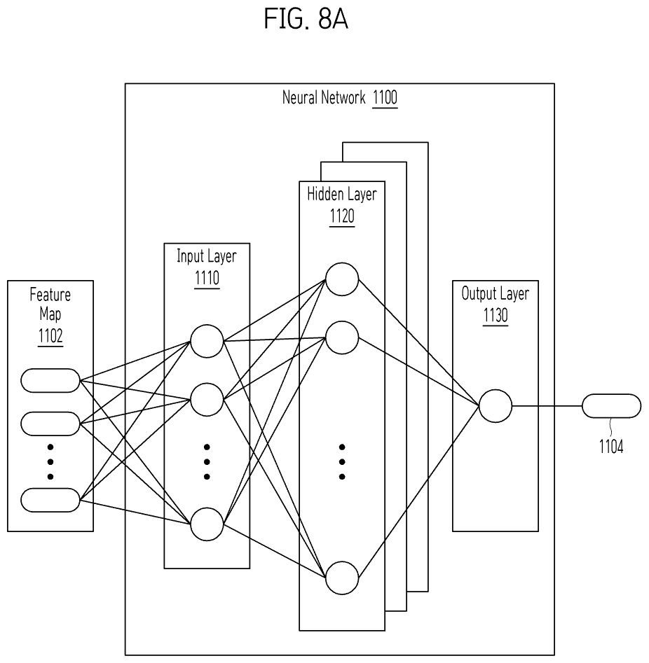

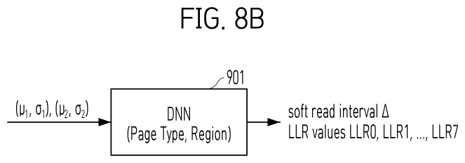

In one embodiment of the present disclosure, a neural network may be used to derive the optimal soft read thresholds and associated log-likelihood ratio (LLR) values. In general, FIG. 8A is a diagram illustrating an example of a neural network 1100 in accordance with one embodiment of the present disclosure where the neural network 1100 is configured (like DNN module 901 of FIG. 8B) to determine a soft read interval Δ, and optimal LLR values. In some embodiments, the neural network 1100 may be included in the control unit 120 of memory controller 100 of FIG. 3.

Referring to FIG. 8A, a feature map 1102 associated with one or more input conditions may input to the neural network 1100. The feature map 1102 includes one or more features associated with one or more input conditions. The neural network 1100 uses the feature map 1102 to generate and output information 1104. As illustrated, the neural network 1100 includes an input layer 1110, one or more hidden layers 1120 and an output layer 1130. Features from the feature map 1102 may be connected to input nodes in the input layer 1110. The information 1104 may be generated from an output node of the output layer 1130. One or more hidden layers 1120 may exist between the input layer 1110 and the output layer 1130. The neural network 1100 may be pre-trained to process the features from the feature map 1102 through the different layers 1110, 1120, and 1130 in order to output the information 1104.

The neural network 1100 may be a multi-layer neural network that represents a network of interconnected nodes, such as an artificial deep neural network, where knowledge about the nodes (e.g., information about specific features represented by the nodes) is shared across layers and knowledge specific to each layer is also retained. Each node represents a piece of information. Knowledge may be exchanged between nodes through node-to-node interconnections. Input to the neural network 1100 may activate a set of nodes. In turn, this set of nodes may activate other nodes, thereby propagating knowledge about the input. This activation process may be repeated across other nodes until nodes in the output layer 1130 are selected and activated.

In one embodiment, the neural network 1100 may include a hierarchy of layers representing a hierarchy of nodes interconnected in a feed-forward way. The input layer 1110 may exist at the lowest hierarchy level. The input layer 1110 as detailed below may include a set of nodes that are referred to herein as input nodes (e.g., accepting the (μ₁, σ₁) and (μ₂, σ₂) inputs of FIG. 8B). When the feature map 1102 is input to the neural network 1100, each of the input nodes of the input layer 1110 may be connected to each feature of the feature map 1102. Each of the connections may have a weight, each of which is derived from the training of the neural network 1100. The weights represent one set of parameters of the neural network 1100. The input nodes may transform the features by applying an activation function to these features. The information derived from the transformation may be passed to the nodes at a higher level of the hierarchy.

The output layer 1130 may exist at the highest hierarchy level. The output layer 1130 may include one or more output nodes. When the output layer 1130 outputs the output information 1104, each output node may provide a specific value of the output information 1104 (e.g., the soft read interval Δ, and optimal LLR values as detailed below). The number of output nodes depends on how many specific values of output information 1104 are needed. In other words, there can be a one-to-one relationship or mapping between the number of output nodes and the number of values or pieces of output information 1104.

The hidden layer(s) 1120 may exist between the input layer 1110 and the output layer 1130. There may be N hidden layer(s) 1120, where “N” is an integer greater than or equal to one. Each of the hidden layers 1120 may include a set of nodes that are referred to herein as hidden nodes. Example hidden layers may include up-sampling, convolutional, fully connected layers, and/or data transformation layers.

At the lowest level of the hidden layer(s) 1120, hidden nodes of that layer may be interconnected to the input nodes. At the highest level of the hidden layer(s) 1120, hidden nodes of that level may be interconnected to the output node. The input nodes may be not directly interconnected to the output node(s). If multiple hidden layers exist, the input nodes are interconnected to hidden nodes of the lowest hidden layer. In turn, these hidden nodes are interconnected to the hidden nodes of the next hidden layer. An interconnection may represent a piece of information learned about the two interconnected nodes. The interconnection may have a numeric weight that can be tuned (e.g., based on a training dataset), rendering the neural network 1100 adaptive to inputs and capable of learning.

Generally, the hidden layer(s) 1120 may allow knowledge about the input nodes of the input layer 1110 to be shared among the output nodes of the output layer 1130. To do so, a transformation ƒ may be applied to the input nodes through the hidden layer 1120. In an example, the transformation ƒ is non-linear. Different non-linear transformations ƒ are available including, for instance, a rectifier function ƒ(x)=max(0, x). In an example, a particular non-linear transformation ƒ is selected based on cross-validation.

### LLR and Soft Read Threshold Generation

In one embodiment of the present disclosure, there is provided a novel method to estimate optimal soft read thresholds and associated log-likelihood ratio (LLR) values for LDPC soft decoding of data read from a memory storage. In this method, each NAND program-voltage (PV) state is modeled as a Gaussian distribution. The mean value μ and standard deviation σ of each PV state are estimated using two read thresholds and associated two survival function values. The two read thresholds and the survival function values can be obtained by two schemes (detailed below). In each LLR region, once the parameters of the two PV states of a read valley are known, these parameters can be input to a trained deep neural network (DNN) to infer optimal soft read interval and optimal LLR values for LDPC soft decoding. For example, for the LSB page, in Region A, the read threshold is R3 and the two adjacent states are PV2 and PV3. Once the survival function of these states PV2 and PV3 are known, the read thresholds and survival functions can be input to the DNN to infer optimal soft read interval and optimal LLR values for LDPC soft decoding. As a result, the LDPC soft correction capability is improved and the SSD reliability is enhanced.

In general, this method may use control unit 120 or control circuit 220 of FIG. 3 to estimate the parameters (mean, standard deviation) of each PV state, and then for each page type and region, a deep neural network DNN (e.g., an offline trained DNN) can be used to infer optimal soft read intervals and optimal LLR values. As shown in FIG. 8B, DNN 901 receives as inputs mean values and standard deviations (μ₁, σ₁) and (μ₂, σ₂) from adjacent PV states and outputs optimal soft read intervals Δ, and optimal LLR values.

### Soft Read Threshold and Surviving Function Determinations

Consider a TLC NAND as an example. Table 1 shows the Gray labeling of each of the eight (8) program-voltage states (PV0, PV1, . . . PV7), as shown in FIG. 7D.

TABLE 1

| | PV0 | PV1 | PV2 | PV3 | PV4 | PV5 | PV6 | PV7 |
|---|---|---|---|---|---|---|---|---|
| MSB | 1 | 0 | 0 | 0 | 0 | 1 | 1 | 1 |
| CSB | 1 | 1 | 0 | 0 | 1 | 1 | 0 | 0 |
| LSB | 1 | 1 | 1 | 0 | 0 | 0 | 0 | 1 |

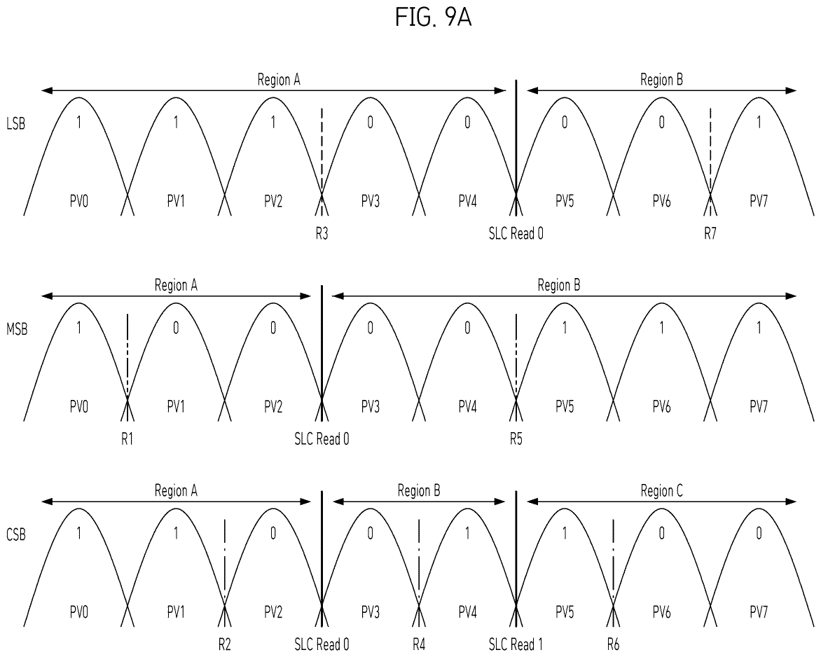

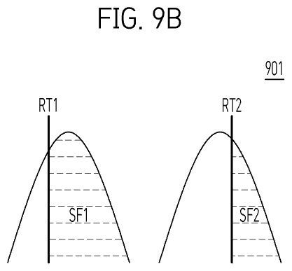

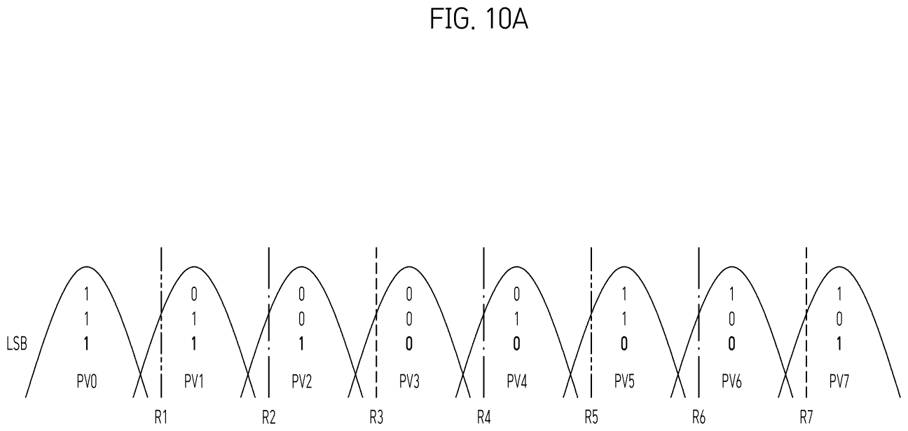

FIG. 9A shows the Gaussian-type PV regions for each page type (MSB, CSB, and LSB) and shows a SLC assist read between the regions of each page type.

Table 2 shows the left and right PV distributions for each page type (MSB, CSB, LSB) and each LLR region (A, B, or C).

TABLE 2

| | Region A | Region B | Region C |
|---|---|---|---|
| MSB | PV0, PV1 | PV4, PV5 | |
| CSB | PV1, PV2 | PV3, PV4 | PV5, PV6 |
| LSB | PV2, PV3 | PV6, PV7 | |

For the LSB page, the intersection of the valley between PV2 and PV3 sets a read threshold R3 (shown in FIG. 9A), and the intersection of the valleys between PV6 and PV7 sets the threshold voltage R7 (shown in FIG. 9A) between these PV states. For the MSB page, the intersection of the valleys between PV0 and PV1 sets the voltage threshold R1 (shown in FIG. 9A) between these PV states, and the intersection of the valleys between PV4 and PV5 sets the voltage threshold R5 (shown in FIG. 9A) between these PV states. For the CSB page, the intersection of the valleys between PV1 and PV2 sets the voltage threshold R2 (shown in FIG. 9A) between these PV states, the intersection of the valleys between PV3 and PV4 sets the voltage threshold R4 (shown in FIG. 9A) between these PV states, and the intersection of the valleys between PV5 and PV6 sets the voltage threshold R6 (shown in FIG. 9A) between these PV states.

In one embodiment of the present disclosure, the following procedure performed by a controller (e.g., control unit 120 or control circuit 220) can generate soft read thresholds and LLR values for soft decoding.
1) Obtain RT1, RT2, SF1, SF2: For each NAND PV state, a controller obtains two read thresholds RT1 and RT2 and two survival function values SF1 and SF2. For a NAND PV state, the survival function value SF associated with the read threshold RT is defined as: X/Y, where X represents the number of cells read from a memory block associated with this PV state that have threshold voltage larger than RT, and Y represents the total number of cells associated with this PV state in the memory block. For a NAND PV state, the read thresholds RT1 and RT2 can be pre-determined where RT1 and RT2 are placed near the PV state peak such that SF1 and SF2 values are in the reliable range [35%, 65%]. A SF value is evaluated at a read threshold (as detailed below). FIG. 9B shows examples regarding RT1, RT2, SF1, SF2 taken for the same NAND PV state. For a PV state, when a read threshold is at the left-most side of the PV distribution, the SF value is 1. For a read threshold anywhere else away from the left-most side of the PV distribution, the SF value is represented by the remaining area to the right of RT divided by the whole area. SF value should be in the range [0, 1]. In one embodiment shown in FIG. 9B, SF1 and SF2 are in a reliable range, e.g., SF2=35%, SF1=65%. If the read threshold RT1 is on the peak, SF1 is 0.5. Accordingly, RT1 and RT2 can be near or at the peak. In one embodiment, RT1 and RT2 are set so that the corresponding SF1 and SF2 values are greater than or equal to 0.35 and less than or equal to 0.65, i.e., in the range [0.35, 0.65]. However, other ranges are suitable for the present disclosure.
2) Estimate (μ, σ): For each PV state, the controller can use the values (RT1, RT2, SF1, SF2) for each Gaussian PV distribution to compute the mean μ and the standard deviation σ of that PV state, that is (μ, σ) of a Gaussian distribution by the following formula:

$$μ = \frac{R T 2 {Φ}^{- 1} ( S F 1 ) - R T 1 {Φ}^{- 1} ( S F 2 )}{{Φ}^{- 1} ( S F 1 ) - {Φ}^{- 1} ( S F 2 )}$$

$$σ = \frac{R T 1 - R T 2}{{Φ}^{- 1} ( S F 1 ) - {Φ}^{- 1} ( S F 2 )}$$

where RT1 and RT2 are two read voltage thresholds, SF1 and SF2 are corresponding survival function values evaluated at RT1 and RT2, φ is the cumulative distribution function (CDF) of the standard normal (Gaussian) distribution, and φ⁻¹ is the inverse function of φ. Suppose X is a normal distribution.

$$F ( x ; μ , σ ) = \frac{1}{σ \sqrt{2 π}} {\int }_{- ∞}^{X} exp ( - \frac{{( x - μ )}^{2}}{2 {σ}^{2}} ) d x .$$

where the parameter μ is the mean or expectation of the distribution. and σ is its standard deviation. Then, the CDF φ of the standard normal distribution would be the integral

$$Φ ( x ) = \frac{1}{\sqrt{2 π}} {\int }_{- ∞}^{x} {e}^{\frac{- {t}^{2}}{2}} dt .$$

Compute cross point: For each page type and LLR region (see FIG. 9A), the controller can obtain, for the two corresponding Gaussian distributions at the read thresholds (e.g., the left PV state and the right PV state described above in Table 2), (μ₁, σ₁) and (μ₂, σ₂) for each of the two corresponding Gaussian distributions. The controller can compute the optimal center read threshold (the cross point of two PVs) RT_{OPT} by the following formula:

$$a = - 1 / {σ}_{1}^{2} + 1 / {σ}_{2}^{2}$$

$$b = 2 ( - {μ}_{2} / {σ}_{2}^{2} + {μ}_{1} / {σ}_{1}^{2} )$$

$$c = {μ}_{2}^{2} / {σ}_{2}^{2} - {μ}_{1}^{2} / {σ}_{1}^{2} + log ( {σ}_{2}^{2} / {σ}_{1}^{2} )$$

$$R {T}_{O P T} = \frac{- b - \sqrt{{b}^{2} - 4 a c}}{2 a}$$

Infer soft read interval and LLR values: For each page type and each LLR region (in FIG. 9A) that is evaluated, the corresponding (μ₁, σ₁) and (μ₂, σ₂) can be input to DNN 901 to infer the optimal soft read intervals Δ, and the optimal LLR values (LLR0, LLR1, LLR2, LLR3, LLR4, LLR5, LLR6, LLR7).

Obtain RT and SF with Scheme One

In this embodiment, RT1, RT2, SF1, SF2 can be obtained with the pattern of a cell defined by 3 bits from 3 page reads, as shown in Table 3. By reading each cell using 3 page reads, 3 bits MSB, CSB, and LSB for each cell are obtained. When a cell has MSB=1, CSB=1, LSB=1, according to Table 3, the pattern of this cell is P0. When a cell has MSB=0, CSB=1, LSB=1, the pattern of this cell is P1. Each of the eight patterns has a unique set of MSB, CSB, LSB bits.

TABLE 3

| Pattern | P0 | P1 | P2 | P3 | P4 | P5 | P6 | P7 |
|---|---|---|---|---|---|---|---|---|
| MSB | 1 | 0 | 0 | 0 | 0 | 1 | 1 | 1 |
| CSB | 1 | 1 | 0 | 0 | 1 | 1 | 0 | 0 |
| LSB | 1 | 1 | 1 | 0 | 0 | 0 | 0 | 1 |

In one embodiment, the average cell count per PV state is designated as λ.

### LSB: Obtain RT1, RT2, SF1, SF2 for PV2, PV3, PV6, and PV7

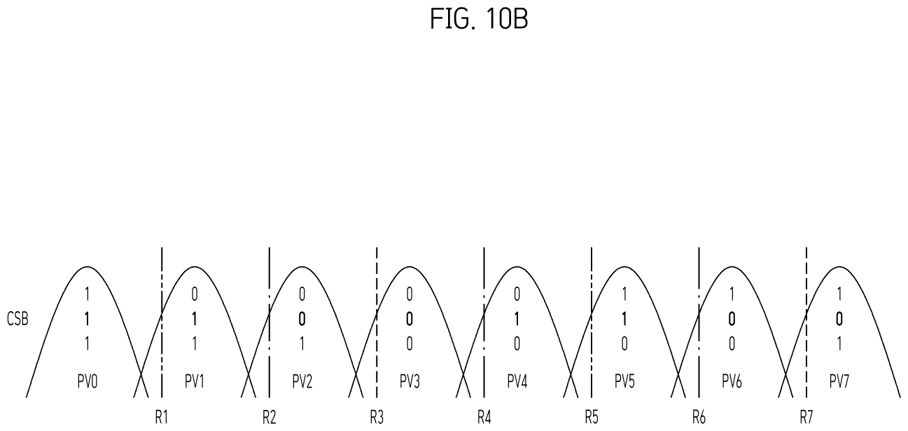

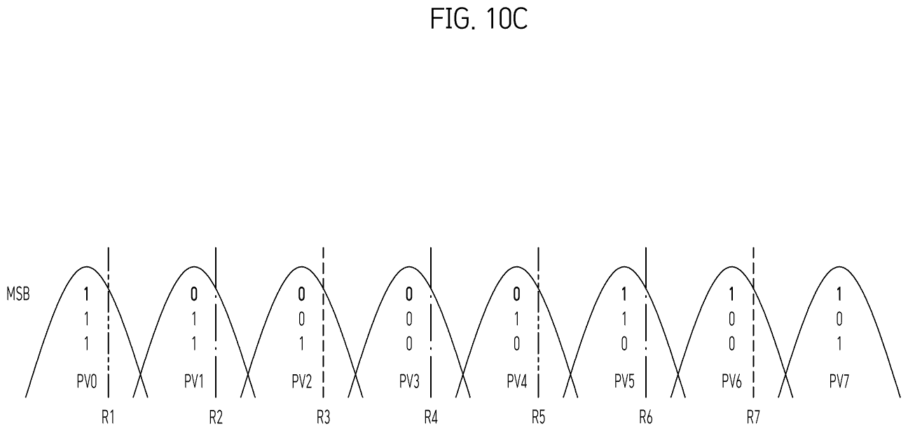

Phase 1: the controller can obtain RT1, SF1 for PV2, PV3, PV6, PV7 as follows
Read LSB(1), CSB(1), and MSB(1). For each cell, a 3 page read is made (i.e., LSB page read, CSB page read, and MSB page read), and the read results are recorded. Here, the notation (1) represents Phase 1, e.g., LSB(1) means a LSB read in Phase 1. The read thresholds are denoted by Ri(1), where i=1, 2, . . . , 7. Ri(1) can be near the peak of PVi, as shown in FIG. 10A.
Compute the cell count of 8 patterns Pᵢ(1), i=0, 1, . . . , 7, using LSB(1), CSB(1), MSB(1). That is, the controller counts the number of cells associated with each pattern realized in the data read, using the three page reads LSB(1), CSB(1), MSB(1) on all eight PV states. For example, the controller counts how many cells have pattern P0 that is LSB=1, CSB=1, MSB=1.

$$( RT 1 , SF 1 ) ( PVi ) = ( Ri ( 1 ) , ( ( i + 1 ) λ - {Σ}_{k = 0}^{i - 1} {P}_{k} ( 1 ) ) / λ ) , i = 2 , 3 , 6 , 7.$$

Here Ri(1) is a notation representing the i^{th} read threshold. For example, R3 and R7 represent LSB read thresholds, R1 and R5 represent MSB read thresholds, and R2, R4, R6 represent CSB read thresholds. The values of read thresholds R1, R2, . . . , R7 are not fixed but can vary. In one embodiment, Ri(1) can be set at any pre-determined placement near or at the peak of PVi such as for example set so that the associated survival function (SF) value on that NAND PV state distribution in the range of [35%, 65%]. However, as before, other ranges are suitable.

In general, the calculated survival function of a PV state can be considered a ratio of a) the number of cells associated with this PV state that have threshold voltage larger than the read threshold RT1 to b) the average cell count for each NAND PV state.

Phase 2: the controller can obtain RT2, SF2 for PV2, PV3, PV6, PV7 as follows:
Read LSB(2) with R3(2) and R7(2), and read CSB(2) with R2(2), R4(2), and R6(2). Here, the notation (2) represents Phase 2,
Compute the cell count of 8 patterns Pᵢ(2), i=0, 1, . . . , 7, using LSB(2), CSB(2), MSB(1).

$$( RT 2 , SF 2 ) ( PVi ) = ( Ri ( 2 ) , ( ( i + 1 ) λ - {Σ}_{k = 0}^{i - 1} {P}_{k} ( 2 ) ) / λ ) , i = 2 , 3 , 6 , 7$$

### CSB: Obtain RT1, RT2, SF1, SF2 for PV1, PV2, PV3, PV4, PV5, and PV6

Phase 1: The controller can obtain RT1, SF1 for PV1, PV2, PV3, PV4, PV5 and PV6 as follows:
Read LSB(1), CSB(1), and MSB(1). As shown in FIG. 10B, the read thresholds are denoted by Ri(1), i=1, 2, . . . , 7. Ri(1) can be at any predetermined placement near or at the peak of PVi.
Compute the cell count of 8 patterns Pᵢ(1), i=0, 1, . . . , 7, using LSB(1), CSB(1), MSB(1).

$$( RT 1 , SF 1 ) ( PVi ) = ( Ri ( 1 ) , ( ( i + 1 ) λ - {\sum }_{k = 0}^{i - 1} {P}_{k} ( 1 ) ) / λ ) , i = 1 , 2 , 3 , 4 , 5 , 6$$

Phase 2: The controller can obtain RT2, SF2 for PV1, PV2, PV3, PV4, PV5 and PV6 as follows:
Read LSB(2) with R3(2) and R7(2), read CSB(2) with R2(2), R4(2), and R6(2), read MSB(2) with R1(2) and R5(2)
Compute the cell count of 8 patterns Pᵢ(2), i=0, 1, . . . , 7, using the values of LSB(2), CSB(2), MSB(2). (RT2, SF2) (PVi)=

$$( RT 2 , SF 2 ) ( PVi ) = ( Ri ( 2 ) , ( ( i + 1 ) λ - {\sum }_{k = 0}^{i - 1} {P}_{k} ( 2 ) ) / λ ) , i = 1 , 2 , 3 , 4 , 5 , 6$$

### MSB: Obtain RT1, RT2, SF1, SF2 for PV0, PV1, PV4, and PV5

Phase 1: The controller can obtain RT1, SF1 for PV0, PV1, PV4, and PV5 as follows:
Read LSB(1), CSB(1), and MSB(1). As shown in FIG. 10C, the read thresholds are denoted by Ri(1), i=1, 2, . . . , 7. Ri(1) can be at any predetermined placement near or at the peak of PV(i−1) such that the associated survival function (SF) value on that NAND PV state is in a range of [35%, 65%]. However, as before, other ranges are suitable.
Compute the cell count of 8 patterns Pᵢ(1), i=0, 1, . . . , 7, using LSB(1), CSB(1), MSB(1)

$$( RT 1 , SF 1 ) ( PVi ) = ( R ( i + 1 ) ( 1 ) , ( ( i + 1 ) λ - {\sum }_{k = 0}^{i} {P}_{k} ( 1 ) ) / λ ) , i = 0 , 1 , 4 , 5$$

Phase 2: The controller can obtain RT2, SF2 for PV0, PV1, PV4, and PV5 as follows:
Read CSB(2) with R2(2), R4(2), and R6(2), and read MSB(2) with R1(2) and R5(2)
Compute the cell count of 8 patterns Pᵢ(2), i=0, 1, . . . , 7, using LSB(1), CSB(2), MSB(2). That is, after the LSB, CSB, and MSB page reads, the controller counts the number of cells for each pattern.

$$( RT 2 , SF 2 ) ( PVi ) = ( R ( i + 1 ) ( 2 ) , ( ( i + 1 ) λ - {\sum }_{k = 0}^{i} {P}_{k} ( 2 ) ) / λ ) , i = 0 , 1 , 4 , 5.$$

Because the reference thresholds have changed positions relative to the peaks of PV states, two values of read thresholds and survival functions are obtained for each PV Gaussian state.
   Obtain RT and SF with Scheme Two

In this scheme, a multi-cell page read and an SLC assist read are used to obtain two read thresholds and surviving functions. Here, as above, the average cell count per PV state is designated as A.

### LSB: Obtain RT1, RT2, SF1, SF2 for PV2, PV3, PV6, and PV7

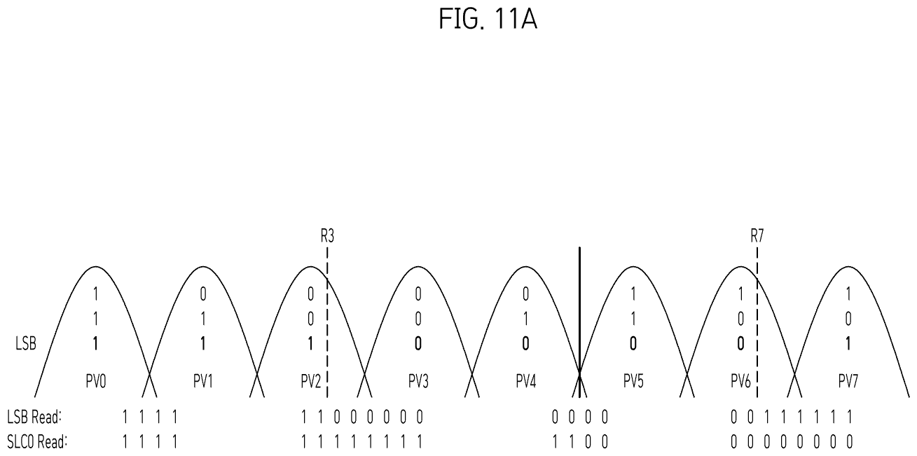

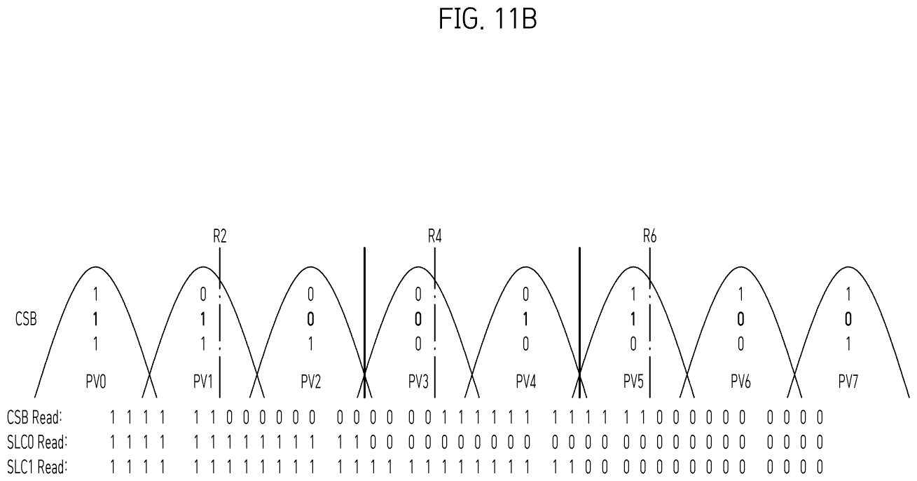

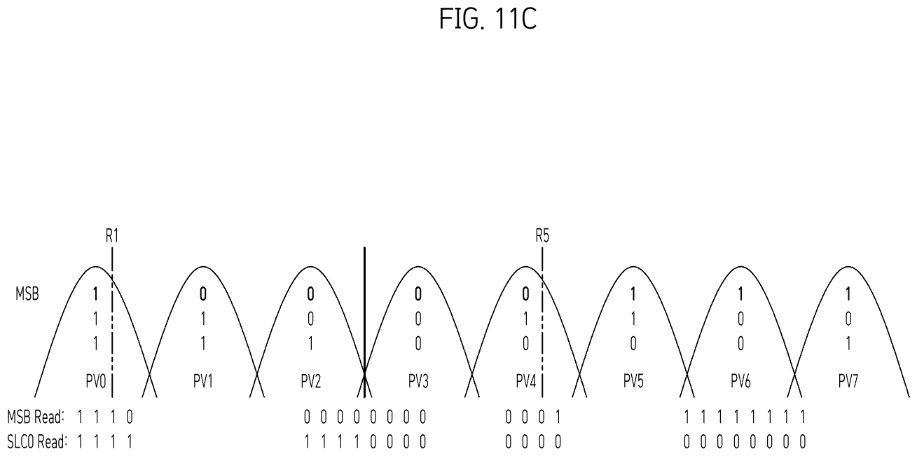

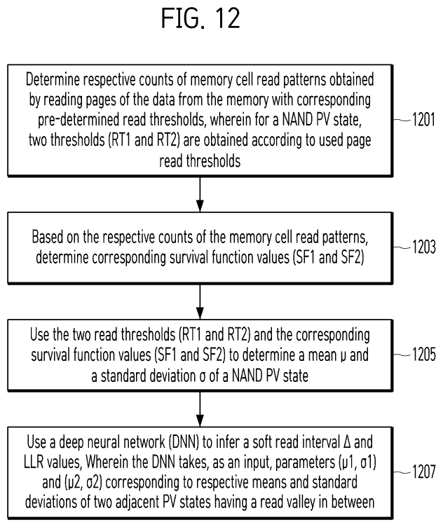

Phase 1: The controller can obtain RT1, SF1 for PV2, PV3, PV6, PV7 as follows:
Read SLC0(1).
Read LSB(1) using R3(1) and R7(1) near the peak of PV2 and PV6 as shown in FIG. 11A. Here, by “read”, the pattern of each cell is determined. Then the number of total cells for each pattern are counted.
Compute the cell count of 4 patterns Pᵢ(1), i=0, 1, 2, 3 using LSB(1) and SLC0(1), according to Table 4.

TABLE 4

| Pattern | P0 | P1 | P2 | P3 |
|---|---|---|---|---|
| LSB | 1 | 0 | 0 | 1 |
| SLC0 | 1 | 1 | 0 | 0 |

$$( RT 1 , SF 1 ) ( PV 2 ) = ( R 3 ( 1 ) , ( 3 λ - {P}_{0} ( 1 ) ) / λ ) , ( RT 1 , SF 1 ) ( PV 6 ) = ( R 7 ( 1 ) , ( 7 λ - {\sum }_{k = 0}^{2} {P}_{k} ( 1 ) ) / λ ) .$$

Similarly, the controller can issue another read LSB(1) command by re-placing R3(1) and R7(1) near the peak of PV3 and PV7, to obtain (RT1, SF1) (PV3) and (RT1, SF1) (PV7).

Phase 2: Obtain RT2, SF2 for PV2, PV3, PV6, PV7
Similarly, the controller can read LSB(2) using R3(2) and R7(2). near the peak of PV2 and PV6 to obtain (RT2, SF2) (PV2) and (RT2, SF2) (PV6).
Similarly, the controller can issue another read LSB(2) command by re-placing R3(2) and R7(2) near the peak of PV3 and PV7 to obtain (RT2, SF2) (PV3) and (RT2, SF2) (PV7).

### CSB: Obtain RT1, RT2, SF1, SF2 for PV1, PV2, PV3, PV4, PV5, and PV6

Phase 1: The controller can obtain RT1, SF1 for PV1, PV2, PV3, PV4, PV5, PV6 as follows:
Read SLC0(1) and read SLC1(1).
Read CSB(1) using R2(1), R4(1), and R6(1) near the peak of PV1, PV3, and PV5 as shown in FIG. 11B.
Compute the cell count of six (6) patterns Pᵢ(1), i=0, 1, 2, 3, 4, 5 using CSB(1), SLC0(1) and SLC1(1), according to Table 5.

TABLE 5

| Pattern | P0 | P1 | P2 | P3 | P4 | P5 |
|---|---|---|---|---|---|---|
| CSB | 1 | 0 | 0 | 1 | 1 | 0 |
| SLC0 | 1 | 1 | 0 | 0 | 0 | 0 |
| SLC1 | 1 | 1 | 1 | 1 | 0 | 0 |

$$( RT 1 , SF 1 ) ( PV 1 ) = ( R 2 ( 1 ) , ( 2 λ - {P}_{0} ( 1 ) ) / λ ) , ( RT 1 , SF 1 ) ( PV 3 ) = ( R 4 ( 1 ) , ( 4 λ - {\sum }_{k = 0}^{2} {P}_{k} ( 1 ) ) / λ ) , ( RT 1 , SF 1 ) ( PV 5 ) = ( R 6 ( 1 ) , ( 6 λ - {\sum }_{k = 0}^{4} {P}_{k} ( 1 ) ) / λ ) .$$

Similarly, the controller can read CSB(1) using R2(1), R4(1), and R6(1) near the peak of PV2, PV4, and PV6, to obtain (RT1, SF1) (PV2), (RT1, SF1) (PV4), and (RT1, SF1) (PV6).

Phase 2: Obtain RT2, SF2 for PV1, PV2, PV3, PV4, PV5, PV6
Similarly, the controller can read CSB(2) using R2(2), R4(2), and R6(2) near the peak of PV1, PV3, and PV5, to obtain (RT2, SF2) (PV1), (RT2, SF2) (PV3), and (RT2, SF2) (PV5).
Similarly, the controller can read CSB(2) using R2(2), R4(2), and R6(2) near the peak of PV2, PV4, and PV6, to obtain (RT2, SF2) (PV2), (RT2, SF2) (PV4), and (RT2, SF2) (PV6).
Here, as demonstrated above, the controller has measured for the PV2 state two survival functions at two read thresholds: a) (RT1, SF1) (PV2) and b) (RT2, SF2) (PV2).

### MSB: Obtain RT1, RT2, SF1, SF2 for PV0, PV1, PV4, and PV5

Phase 1: The controller can obtain RT1, SF1 for PV0, PV1, PV4, PV5 as follows:
Read SLC0(1).
Read MSB(1) using R1(1) and R5(1) near the peak of PV0 and PV4 as shown in FIG. 11C.
Compute the cell count of 4 patterns Pᵢ(1), i=0, 1, 2, 3 using MSB(1) and SLC0(1), according to Table 6.

TABLE 6

| Pattern | P0 | P1 | P2 | P3 |
|---|---|---|---|---|
| MSB | 1 | 0 | 0 | 1 |
| SLC0 | 1 | 1 | 0 | 0 |

$$( RT 1 , SF 1 ) ( PV 0 ) = ( R 1 ( 1 ) , ( λ - {P}_{0} ( 1 ) ) / λ ) , ( RT 1 , SF 1 ) ( PV 4 ) = ( R 5 ( 1 ) , ( 5 λ - {\sum }_{k = 0}^{2} {P}_{k} ( 1 ) ) / λ ) .$$

Similarly, the controller can read MSB(1) using R1(1) and R5(1) near the peak of PV1 and PV5 to obtain (RT1, SF1) (PV1) and (RT1, SF1) (PV5).

Phase 2: Obtain RT2, SF2 for PV0, PV1, PV4, PV5
Similarly, the controller can read MSB(2) using R1(2) and R5(2) near the peak of PV0 and PV4 to obtain (RT2, SF2) (PV0) and (RT2, SF2) (PV4).
Similarly, the controller can read MSB(2) using R1(2) and R5(2) near the peak of PV1 and PV5 to obtain (RT2, SF2) (PV1) and (RT2, SF2) (PV5).

### Inventive Method

In one embodiment of the present invention, there is provided a method for estimating parameters for reading data from a memory having a plurality of NAND program-voltage (PV) states. The method at 1201 determines respective counts of memory cell read patterns obtained by reading pages of the data (with or without SLC read) from the memory with corresponding pre-determined read thresholds, wherein for a NAND PV state, two thresholds (RT1 and RT2) are obtained according to used page read thresholds. The method at 1203 based on the respective counts of the memory cell read patterns, determines corresponding survival function values (SF1 and SF2). The method at 1205 uses the two read thresholds (RT1 and RT2) and the corresponding survival function values (SF1 and SF2) to determine a mean μ and a standard deviation σ of a NAND PV state. The method at 1207 uses a deep neural network (DNN) to infer a soft read interval Δ and LLR values. Here, the DNN takes, as an input, parameters (μ₁, σ₁) and (μ₂, σ₂) corresponding to respective means and standard deviations of two adjacent PV states having a read valley in between.

In one method embodiment, the following equations are used to calculate the mean μ and the standard deviation σ of the NAND PV state:

$$\begin{matrix}μ = \frac{R T 2 {Φ}^{- 1} ( S F 1 ) - R T 1 {Φ}^{- 1} ( SF 2 )}{{Φ}^{- 1} ( S F 1 ) - {ϕ}^{- 1} ( S F 2 )} \\ σ = \frac{R T 1 - R T 2}{{Φ}^{- 1} ( S F 1 ) - {Φ}^{- 1} ( S F 2 )}\end{matrix}$$

where RT1 and RT2 are two read voltage thresholds, SF1 and SF2 are corresponding survival function values evaluated at RT1 and RT2, φ is the cumulative distribution function (CDF) of a standard Gaussian distribution, and φ⁻¹ is the inverse function of φ.

In one method embodiment, in the DNN each NAND PV state is modeled as a Gaussian distribution; and in the DNN crossing points in the read valley between the two adjacent NAND PV states are determined.

In one method embodiment, a read threshold for reading data from one of the two adjacent NAND PV states is determined, wherein the read threshold comprises an optimal read threshold RT_OPT defined by:

$$\begin{matrix}a = - 1 / {σ}_{1}^{2} + 1 / {σ}_{2}^{2} \\ b = 2 ( - {μ}_{2} / {σ}_{2}^{2} + {μ}_{1} / {σ}_{1}^{2} ) \\ c = {μ}_{2}^{2} / {σ}_{2}^{2} - {μ}_{1}^{2} / {σ}_{1}^{2} + log ( {σ}_{2}^{2} / {σ}_{1}^{2} ) \\ {RT}_{O P T} = \frac{- b - \sqrt{{b}^{2} - 4 a c}}{2 a}\end{matrix}$$

where μ₁, σ₁, μ₂, and σ₂ are the respective means and standard deviations for the two adjacent PV states.

In one method embodiment, the determining of the respective counts of the memory cell read patterns comprises reading a least significant bit (LSB) page, a center significant bit (CSB) page, and a most significant bit (MSB) page of the memory; and for each of eight patterns of 1s and 0s read for the LSB, CSB, and MSB, count numbers of cells with each of the eight patterns.

In one method embodiment, the determining corresponding survival function values comprises calculating, in a first phase based on reading the memory with the RT1, the SF1 of a PV state based on a ratio of a) a number of cells associated with the PV state that have threshold voltages larger than the read threshold RT1 according to the eight patterns to b) an average cell count for each NAND PV state.

In one method embodiment, the determining corresponding survival function values comprises calculating, in a second phase based on reading the memory with the RT2, the SF2 of a PV state based on a ratio of a) a number of cells associated with the PV state that have threshold voltages larger than the read threshold RT2 according to the eight patterns to b) the average cell count for each NAND PV state.

In one method embodiment, the determining of the respective counts of the memory cell read patterns comprises reading a single layer cell (SLC) bit and a least significant bit (LSB) page; and for each of four patterns of 1s and 0s read for the SLC and LSB, count numbers of cells with each of the four patterns.

In one method embodiment, the determining corresponding survival function values comprises: calculating, in a first phase based on reading the memory with the RT1, the SF1 of a PV state based on a ratio of a) a number of cells associated with the PV state that have threshold voltages larger than the read threshold RT1 according to the four patterns to b) an average cell count for each NAND PV state

In one method embodiment, the determining corresponding survival function values comprises calculating, in a second phase based on reading the memory with the RT2, the SF2 of a PV state based on a ratio of a) a number of cells associated with the PV state that have threshold voltages larger than the read threshold RT2 according to the four patterns to b) the average cell count for each NAND PV state.

### Memory System

In one embodiment of the present invention, there is provided a memory system (such as memory system 20 in FIG. 3) having a storage (such as for example semiconductor memory device 200 in FIG. 3) and a controller (such as for example memory controller 100 in FIG. 3) in communication with the storage and configured to: determine respective counts of memory cell read patterns obtained by reading pages of the data (with or without SLC read) from the memory with corresponding pre-determined read thresholds, wherein for a NAND PV state, two thresholds (RT1 and RT2) are obtained according to used page read thresholds; based on the respective counts of the memory cell read patterns, determine corresponding survival function values (SF1 and SF2); use the two read thresholds (RT1 and RT2) and the corresponding survival function values (SF1 and SF2) to determine a mean μ and a standard deviation σ of a NAND PV state; and use a deep neural network (DNN) to infer a soft read interval Δ and LLR values, wherein the DNN takes, as an input, parameters (μ₁, σ₁) and (μ₂, σ₂) corresponding to respective means and standard deviations of two adjacent PV states having a read valley in between.

In this memory system, the controller is configured to calculate the mean μ and the standard deviation σ of the NAND PV state, with the following equations:

$$\begin{matrix}μ = \frac{R T 2 {Φ}^{- 1} ( S F 1 ) - R T 1 {Φ}^{- 1} ( SF 2 )}{{Φ}^{- 1} ( S F 1 ) - {ϕ}^{- 1} ( S F 2 )} \\ σ = \frac{R T 1 - R T 2}{{Φ}^{- 1} ( S F 1 ) - {Φ}^{- 1} ( S F 2 )}\end{matrix}$$

where RT1 and RT2 are two read voltage thresholds, SF1 and SF2 are corresponding survival function values evaluated at RT1 and RT2, φ is the cumulative distribution function (CDF) of a standard Gaussian distribution, and φ⁻¹ is the inverse function of φ.

In this memory system, the controller is configured to model in the DNN each NAND PV state as a Gaussian distribution; and determine in the DNN crossing points in the read valley between the two adjacent NAND PV states.

In this memory system, the controller is configured to determine a read threshold for reading data from one of the two adjacent NAND PV states, wherein the read threshold comprises an optimal read threshold RT_OPT defined by:

$$\begin{matrix}a = - 1 / {σ}_{1}^{2} + 1 / {σ}_{2}^{2} \\ b = 2 ( - {μ}_{2} / {σ}_{2}^{2} + {μ}_{1} / {σ}_{1}^{2} ) \\ c = {μ}_{2}^{2} / {σ}_{2}^{2} - {μ}_{1}^{2} / {σ}_{1}^{2} + log ( {σ}_{2}^{2} / {σ}_{1}^{2} ) \\ {RT}_{O P T} = \frac{- b - \sqrt{{b}^{2} - 4 a c}}{2 a}\end{matrix}$$

where μ₁, σ₁, μ₂, and σ₂ are the respective means and standard deviations for the two adjacent PV states.

In this memory system, the controller is configured to read a least significant bit (LSB) page, a center significant bit (CSB) page, and a most significant bit (MSB) page of the memory; and for each of eight patterns of 1s and 0s read from the LSB page, the CSB page, and the MSB page, count numbers of cells with each of the eight patterns.

In this memory system, the controller is configured to

In this memory system, the controller is configured to calculate, in a first phase based on reading the memory with the RT1, the SF1 of a PV state based on a ratio of a) a number of cells associated with the PV state that have threshold voltages larger than the read threshold RT1 according to the eight patterns to b) an average cell count for each NAND PV state.

In this memory system, the controller is configured to calculate, in a second phase based on reading the memory with the RT2, the SF2 of a PV state based on a ratio of a) a number of cells associated with the PV state that have threshold voltages larger than the read threshold RT2 according to the eight patterns to b) the average cell count for each NAND PV state.

In this memory system, the controller is configured to read a single layer cell (SLC) page and a least significant bit (LSB) page; and for each of four patterns of 1s and 0s read from the SLC page and the LSB page, count numbers of cells with each of the four patterns.

In this memory system, the controller is configured to calculate, in a first phase based on reading the memory with the RT1, the SF1 of a PV state based on a ratio of a) a number of cells associated with the PV state that have threshold voltages larger than the read threshold RT1 according to the four patterns to b) an average cell count for each NAND PV state.

In this memory system, the controller is configured to calculate, in a second phase based on reading the memory with the RT2, the SF2 of a PV state based on a ratio of a) a number of cells associated with the PV state that have threshold voltages larger than the read threshold RT2 according to the four patterns to b) the average cell count for each NAND PV state.

Although the foregoing embodiments have been described in some detail for purposes of clarity of understanding, the invention is not limited to the details provided. There are many alternative ways of implementing the invention. The disclosed embodiments are illustrative and not restrictive. The present invention is intended to embrace all modifications and alternatives of the disclosed embodiment. Furthermore, the disclosed embodiments may be combined to form additional embodiments.

Indeed, implementations of the subject matter and the functional operations described in this patent document can be implemented in various systems, digital electronic circuitry, or in computer software, firmware, or hardware, including the structures disclosed in this specification and their structural equivalents, or in combinations of one or more of them. Implementations of the subject matter described in this specification can be implemented as one or more computer program products, i.e., one or more modules of computer program instructions encoded on a tangible and non-transitory computer readable medium for execution by, or to control the operation of, data processing apparatus. The computer readable medium can be a machine-readable storage device, a machine-readable storage substrate, a memory device, a composition of matter effecting a machine-readable propagated signal, or a combination of one or more of them. The term “data processing unit” or “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them.

A computer program (also known as a program, software, software application, script, or code) can be written in any form of programming language, including compiled or interpreted languages, and it can be deployed in any form, including as a stand-alone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of non-volatile memory, media and memory devices, including by way of example semiconductor memory devices, e.g., EPROM, EEPROM, and flash memory devices. The processor and the memory can be supplemented by, or incorporated in, special purpose logic circuitry.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations, one or more features from a combination can in some cases be excised from the combination, and the combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described and other implementations, enhancements and variations can be made based on what is described and illustrated in this patent document.

What is claimed is:

1. A method for estimating parameters for reading data from a memory having a plurality of NAND program-voltage (PV) states, comprising:
determining respective counts of memory cell read patterns obtained by reading pages of the data from the memory with corresponding pre-determined read thresholds, wherein for a NAND PV state, two thresholds (RT1 and RT2) are obtained according to used page read thresholds;
based on the respective counts of the memory cell read patterns, determining corresponding survival function values (SF1 and SF2);
using the two read thresholds (RT1 and RT2) and the corresponding survival function values (SF1 and SF2) to determine a mean μ and a standard deviation σ of a NAND PV state; and
using a deep neural network (DNN) to infer a soft read interval Δ and LLR values, wherein the DNN takes, as an input, parameters (μ₁, σ₁) and (μ₂, σ₂) corresponding to respective means and standard deviations of two adjacent PV states having a read valley in between.

2. The method of claim 1, wherein the mean μ and the standard deviation σ of the NAND PV state is determined with the following equations:
$${Φ}^{- 1} ( S F 1 ) - {Φ}^{- 1} ( S F 2 )$$
where RT1 and RT2 are two read voltage thresholds, SF1 and SF2 are corresponding survival function values evaluated at RT1 and RT2, φ is the cumulative distribution function (CDF) of a standard Gaussian distribution, and φ⁻¹ is the inverse function of φ.

3. The method of claim 1, further comprising:
modeling in the DNN each NAND PV state as a Gaussian distribution; and
determining in the DNN crossing points in the read valley between the two adjacent NAND PV states.

4. The method of claim 3, further comprising:
determining a read threshold for reading data from one of the two adjacent NAND PV states, wherein the read threshold comprises an optimal read threshold RT_OPT defined by:
$$R {T}_{O P T} = \frac{\text{?}}{2 a}$$
$$\text{?} \text{indicates text missing or illegible when filed}$$
where μ₁, σ₁, μ₂, and σ₂ are the respective means and standard deviations for the two adjacent PV states.

5. The method of claim 1, wherein the determining of the respective counts of the memory cell read patterns comprises:
reading a least significant bit (LSB) page, a center significant bit (CSB) page, and a most significant bit (MSB) page of the memory; and
for each of eight patterns of ones (1s) and zeros (0s) read from the LSB page, the CSB page, and the MSB page, counting numbers of cells with each of the eight patterns.

6. The method of claim 5, wherein the determining corresponding survival function values comprises:
calculating, in a first phase based on reading the memory with the RT1, the SF1 of a PV state based on a ratio of a) a number of cells associated with the PV state that have threshold voltages larger than the read threshold RT1 according to the eight patterns to b) an average cell count for each NAND PV state.

7. The method of claim 6, wherein the determining corresponding survival function values comprises:
calculating, in a second phase based on reading the memory with the RT2, the SF2 of a PV state based on a ratio of a) a number of cells associated with the PV state that have threshold voltages larger than the read threshold RT2 according to the eight patterns to b) the average cell count for each NAND PV state.

8. The method of claim 1, wherein the determining of the respective counts of the memory cell read patterns comprises:
reading a single level cell (SLC) page and a least significant bit (LSB) page; and
for each of four patterns of ones (1s) and zeros (0s) read from the SLC page and the LSB page, counting numbers of cells with each of the four patterns.

9. The method of claim 8, wherein the determining corresponding survival function values comprises:
calculating, in a first phase based on reading the memory with the RT1, the SF1 of a PV state based on a ratio of a) a number of cells associated with the PV state that have threshold voltages larger than the read threshold RT1 according to the four patterns to b) an average cell count for each NAND PV state.

10. The method of claim 9, wherein the determining corresponding survival function values comprises:
calculating, in a second phase based on reading the memory with the RT2, the SF2 of a PV state based on a ratio of a) a number of cells associated with the PV state that have threshold voltages larger than the read threshold RT2 according to the four patterns to b) the average cell count for each NAND PV state.

11. A memory system, comprising:
a storage having a plurality of NAND program-voltage (PV) states therein; and
a controller in communication with the storage and configured to
determine respective counts of memory cell read patterns obtained by reading pages of data from the memory with corresponding pre-determined read thresholds, wherein for a NAND PV state, two thresholds (RT1 and RT2) are obtained according to used page read thresholds;
based on the respective counts of the memory cell read patterns, determine corresponding survival function values (SF1 and SF2);
use the two read thresholds (RT1 and RT2) and the corresponding survival function values (SF1 and SF2) to determine a mean μ and a standard deviation σ of a NAND PV state; and
use a deep neural network (DNN) to infer a soft read interval Δ and LLR values, wherein the DNN takes, as an input, parameters parameters (μ₁, σ₁) and (μ₂, σ₂) corresponding to respective means and standard deviations of two adjacent PV states having a read valley in between.

12. The memory system of claim 11, wherein the controller is configured to:
calculate the mean μ and the standard deviation σ of the NAND PV state, with the following equations:
$${ϕ}^{- 1} ( S F 1 ) - {ϕ}^{- 1} ( SF 2 )$$
where RT1 and RT2 are two read voltage thresholds, SF1 and SF2 are corresponding survival function values evaluated at RT1 and RT2, φ is the cumulative distribution function (CDF) of a standard Gaussian distribution, and φ₋₁ is the inverse function of φ.

13. The memory system of claim 12, wherein the controller is configured to:
model in the DNN each NAND PV state as a Gaussian distribution; and
determine in the DNN crossing points in the read valley between the two adjacent NAND PV states.

14. The memory system of claim 13, wherein the controller is configured to:
determine a read threshold for reading data from one of the two adjacent NAND PV states, wherein the read threshold comprises an optimal read threshold RT_OPT defined by:
$$R {T}_{O P T} = \frac{\text{?}}{2 a}$$
$$\text{?} \text{indicates text missing or illegible when filed}$$
where μ₁, σ₁, μ₂, and σ₂ are the respective means and standard deviations for the two adjacent PV states.

15. The memory system of claim 11, wherein the controller is configured to:
read a least significant bit (LSB) page, a center significant bit (CSB) page, and a most significant bit (MSB) page of the memory; and
for each of eight patterns of 1s and 0s read from the LSB page, the CSB page, and the MSB page, count numbers of cells with each of the eight patterns.

16. The memory system of claim 15, wherein the controller is configured to calculate, in a first phase based on reading the memory with the RT1, the SF1 of a PV state based on a ratio of a) a number of cells associated with the PV state that have threshold voltages larger than the read threshold RT1 according to the eight patterns to b) an average cell count for each NAND PV state.

17. The memory system of claim 16, wherein the controller is configured to: calculate, in a second phase based on reading the memory with the RT2, the SF2 of a PV state based on a ratio of a) a number of cells associated with the PV state that have threshold voltages larger than the read threshold RT2 according to the eight patterns to b) the average cell count for each NAND PV state.

18. The memory system of claim 14, wherein the controller is configured to read a single layer cell (SLC) page and a least significant bit (LSB) page; and
for each of four patterns of 1s and 0s read from the SLC page and the LSB page, count numbers of cells with each of the four patterns.

19. The memory system of claim 18, wherein the controller is configured to calculate, in a first phase based on reading the memory with the RT1, the SF1 of a PV state based on a ratio of a) a number of cells associated with the PV state that have threshold voltages larger than the read threshold RT1 according to the four patterns to b) an average cell count for each NAND PV state.

20. The memory system of claim 19, wherein the controller is configured to calculate, the SF2 of a PV state based on a ratio of a) a number of cells associated with the PV state that have threshold voltages larger than the read threshold RT2 according to the four patterns to b) the average cell count for each NAND PV state.
